(19) United States
(12) Patent Application Publication
(10) Pub. No.: US 2026/0255497 A1
(43) Pub. Date: Aug. 27, 2026

(54) METHOD FOR MANUFACTURING CIRCUIT BOARD, APPARATUS FOR PACKAGING CIRCUIT BOARD, AND ELECTRONIC APPARATUS

(71) Applicant: Samsung Display Co., LTD., Yongin-si (KR)

(72) Inventors: WONTAE KIM, Yongin-si (KR); JAE-HAN LEE, Yongin-si (KR)

(21) Appl. No.: 19/405,921

(22) Filed: Dec. 2, 2025

(30) Foreign Application Priority Data
Feb. 26, 2025 (KR) 10-2025-0025081

(51) Int. Cl. H05K 3/22; G06F 1/16; H05K 1/02; H05K 1/181; H05K 3/303; H05K 13/00; H05K 13/08

(52) U.S. Cl. CPC H05K 3/225; G06F 1/1658; H05K 1/0271; H05K 1/181; H05K 3/303; H05K 13/0069; H05K 13/08; H05K 2201/10128; H05K 2203/0195; H05K 2203/1105

(57) ABSTRACT

A method for manufacturing a circuit board includes preparing a base layer on which a pad area is defined, placing a first metal layer on a top surface of the base layer, placing a bump overlapping the pad area, on a top surface of the first metal layer, when viewed in a thickness direction of the base layer, placing a driving chip on a top surface of the bump, placing a reel on a bottom surface of the base layer, rotating the reel in a first rotation direction to wind the base layer, the first metal layer, the bump, and the driving chip to be disposed inside the reel, and applying heat to the reel to package the reel.

This application claims priority to Korean Patent Application No. 10-2025-0025081, filed on February 26, 2025, and all the benefits accruing therefrom under 35 U.S.C. §119, the content of which in its entirety is herein incorporated by reference.

### BACKGROUND

### (1) Field

The present disclosure herein relates to a method for manufacturing a circuit board, an apparatus for packaging a circuit board, and an electronic apparatus including the circuit board.

### (2) Description of the Related Art

Various display devices used in multimedia equipment such as televisions, mobile phones, table computers, navigation devices, and game consoles are being developed.

Such a display device typically includes a display panel on which an image is displayed. The display panel may include a plurality of gate lines, a plurality of data lines, and a plurality of pixels connected to the plurality of gate lines and the plurality of data lines. The display panel may be connected to a circuit board and electronic components that provide electrical signals required for displaying images to gate lines or data lines.

In such a display device, the circuit board and electronic components may be electrically connected to the display panel in various ways. For example, a conductive adhesive member may be disposed between a pad of the circuit board and a pad of the display panel, thereby electrically connecting the circuit board and the display panel.

### SUMMARY

The present disclosure provides a method for manufacturing a circuit board in which a degree of deflection of a circuit board is improved.

The present disclosure also provides an apparatus for packaging a circuit board in which a degree of deflection of a circuit board is improved.

The present disclosure also provides an electronic apparatus including a circuit board with an improved degree of deflection..

An embodiment of the invention provides a method for manufacturing a circuit board, the method including: preparing a base layer on which a pad area is defined; placing a first metal layer on a top surface of the base layer; placing a bump overlapping the pad area, on a top surface of the first metal layer, when viewed in a thickness direction of the base layer; placing a driving chip on a top surface of the bump; placing a reel on a bottom surface of the base layer; rotating the reel in a first rotation direction to wind the base layer, the first metal layer, the bump, and the driving chip to be disposed inside the reel; and applying heat to the reel to package the reel.

In an embodiment, the method may further include placing a second metal layer on the first metal layer.

In an embodiment, the method may further include inspecting electrical connections between the first metal layer, the bump, and the driving chip.

In an embodiment, the applying of the heat to the reel may be performed at about 100°C or lower.

In an embodiment, the reel may include a center portion, and a distance between the driving chip and the center portion may be greater than a distance between the base layer, which is in contact with the driving chip, and the center portion.

In an embodiment, the method may further include rotating the reel in a second rotation direction opposite the first rotation direction to unwind the base layer.

In an embodiment of the invention, an apparatus for packaging a circuit board includes: a reel which rotates in a first rotation direction and a second rotation direction opposite to the first rotation direction; and a circuit board disposed inside the reel, where the circuit board includes: a base layer on which a pad area is defined; a first metal layer disposed on a top surface of the base layer; a bump overlapping the pad area, disposed on a top surface of the first metal layer, when viewed in a thickness direction of the base layer; and a driving chip disposed on a top surface of the bump, where the reel is disposed on a bottom surface of the base layer.

In an embodiment, the circuit board may further include a second metal layer disposed on the first metal layer.

In an embodiment, the first metal layer, the bump, and the driving chip may be electrically connected to each other.

In an embodiment, the reel and the circuit board may be thermally deformed.

In an embodiment, the reel may include a center portion, and a distance between the driving chip and the center portion may be greater than a distance between the base layer, which is in contact with the driving chip, and the center portion.

In an embodiment, the reel may be rotated in the first rotation direction to place the circuit board inside the reel.

In an embodiment, the reel may be rotated in the second rotation direction to place the circuit board outside the reel.

In an embodiment of the invention, an electronic apparatus includes: a display device which displays an image; and a processor which processes an image signal and provides the processed image signal to the display device, where the display device includes a circuit board manufactured by: preparing a base layer on which a pad area is defined; placing a first metal layer on a top surface of the base layer; placing a bump overlapping the pad area, on a top surface of the first metal layer, when viewed in a thickness direction of the base layer; placing a driving chip on a top surface of the bump; placing a reel on a bottom surface of the base layer; rotating the reel in a first rotation direction to wind the base layer; applying heat to the reel; rotating the reel in a second rotation direction opposite to the first rotation direction to unwind the base layer; and rotating the reel in the first rotation direction to place the base layer, the first metal layer, the bumps, and the driving chip inside the reel to perform the packaging.

In an embodiment, the circuit board may further include a second metal layer disposed on the first metal layer.

In an embodiment, the first metal layer, the bump, and the driving chip may be electrically connected to each other.

In an embodiment, the reel and the circuit board may be thermally deformed.

In an embodiment, the reel may include a center portion, and a distance between the driving chip and the center portion may be greater than a distance between the base layer in contact with the driving chip and the center portion.

### BRIEF DESCRIPTION OF THE DRAWINGS

The above and other features of embodiments of the invention will become more apparent by describing in further detail embodiments thereof with reference to the accompanying drawings, in which:

FIG. 1 is a block diagram of an electronic apparatus according to an embodiment of the invention;

FIG. 2 is schematic views of the electronic apparatus according to an embodiment of the invention;

FIG. 3 is a plan view of the electronic apparatus according to an embodiment of the invention;

FIG. 4 is a cross-sectional view taken along line I-I' of FIG. 3;

FIG. 5 is a cross-sectional view of some of components illustrated in FIG. 3;

FIG. 6 is a plan view of some of the components illustrated in FIG. 3;

FIG. 7 is a cross-sectional view of an apparatus for packaging a circuit board according to an embodiment of the invention;

FIGS. 8 and 9 are cross-sectional views illustrating an inside of a reel according to embodiments of the invention; and

FIG. 10 is a flowchart of a method for manufacturing the circuit board according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will also be understood that when one component (or region, layer, portion) is referred to as being ‘on’, ‘connected to’, or ‘coupled to’ another component, it can be directly disposed/connected/coupled on/to the one component, or an intervening third component may also be present.

Like numbers refer to like elements throughout. Also, in the figures, the thickness, ratio, and dimensions of components are exaggerated for clarity of illustration.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by a person of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention are described with reference to the accompanying drawings.

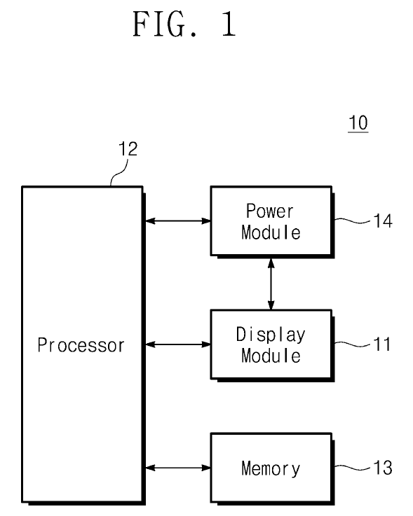

FIG. 1 is a block diagram of an electronic apparatus according to an embodiment of the invention.

Referring to FIG. 1, an embodiment of the electronic apparatus 10 may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), or a control. The processor 12 may process the image signal and provide the image signal to the display device.

The memory 13 may store data information used for the operation of the processor 12 or the display module 11. When the processor 12 executes an application stored in the memory 13, an image data signal and/or an input control signal may be transmitted to the display module 11, and the display module 11 may process the received signal to output image information through a display screen.

The power module 14 may include a power supply module, such as a power adapter or a battery device, and a power conversion module that converts the power supplied by the power supply module to generate the power used for the operation of the electronic apparatus 10.

At least one of the components of the above-described electronic apparatus 10 may be included in the display device according to the above-described embodiments. In addition, a part of the individual modules functionally included in a single module may be included in the display device, and the other part may be provided separately from the display device. In an embodiment, for example, the display device may include the display module 11, and the processor 12, the memory 13, and the power module 14 may be provided in the type of another device within the electronic apparatus 10 rather than in the display device.

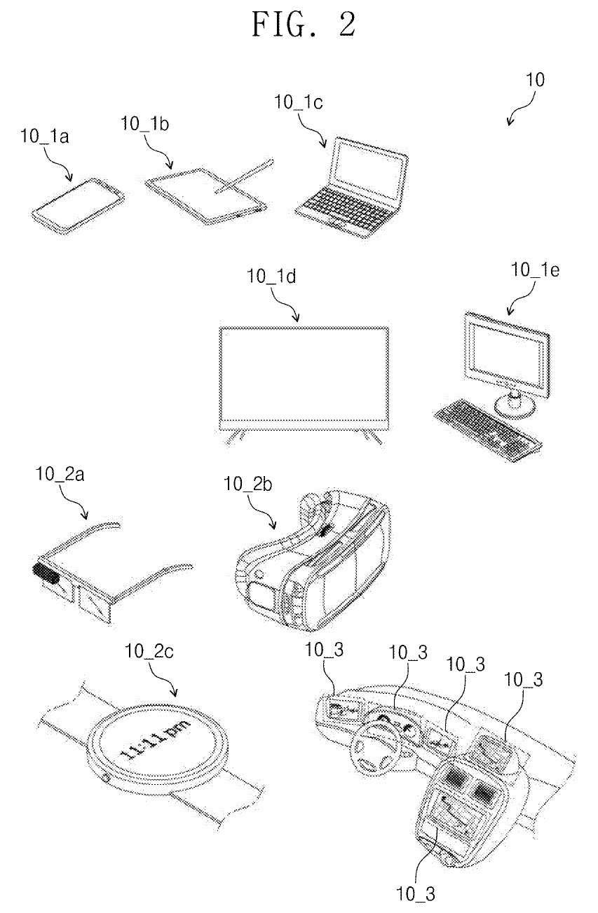

FIG. 2 is schematic views of the electronic apparatus according to an embodiment of the invention.

Referring to FIG. 2, various electronic apparatus to which the display device according to the embodiments is applied may include image display electronic apparatus such as a smartphone 10_1a, a tablet personal computer (PC) 10_1b, a laptop computer 10_1c, a television (TV) 10_1d, and a desktop monitor 10_1e; wearable electronic apparatus including a display module, such as smart glasses 10_2a, a head-mounted display 10_2b, and a smart watch 10_2c; and vehicle electronic apparatus including a display module, such as a center information display (CID), a room mirror display, or a cluster, center fascia, or dashboard of a vehicle. The electronic apparatus may provide the image and include the display device.

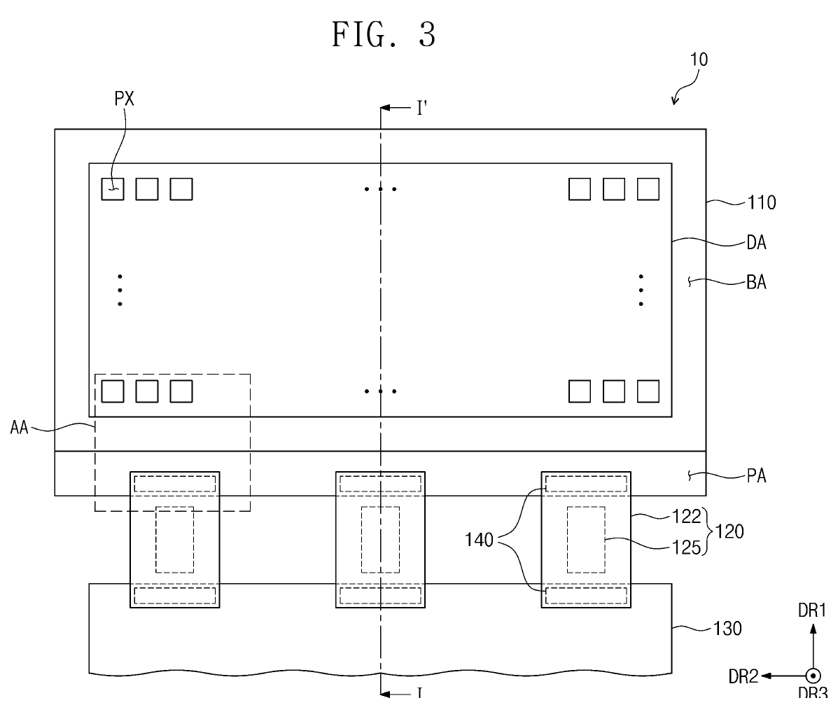

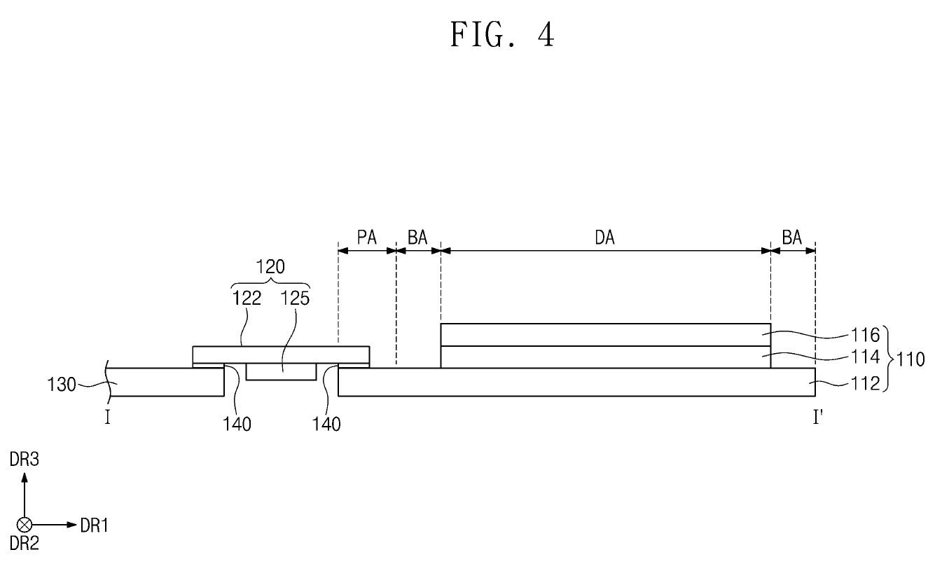

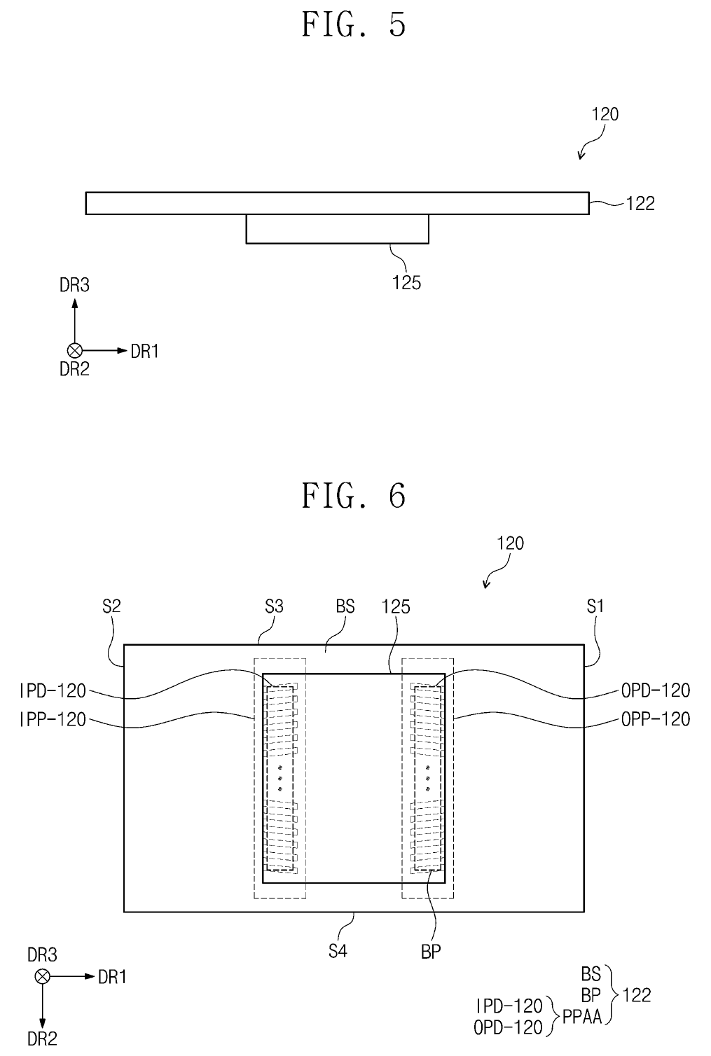

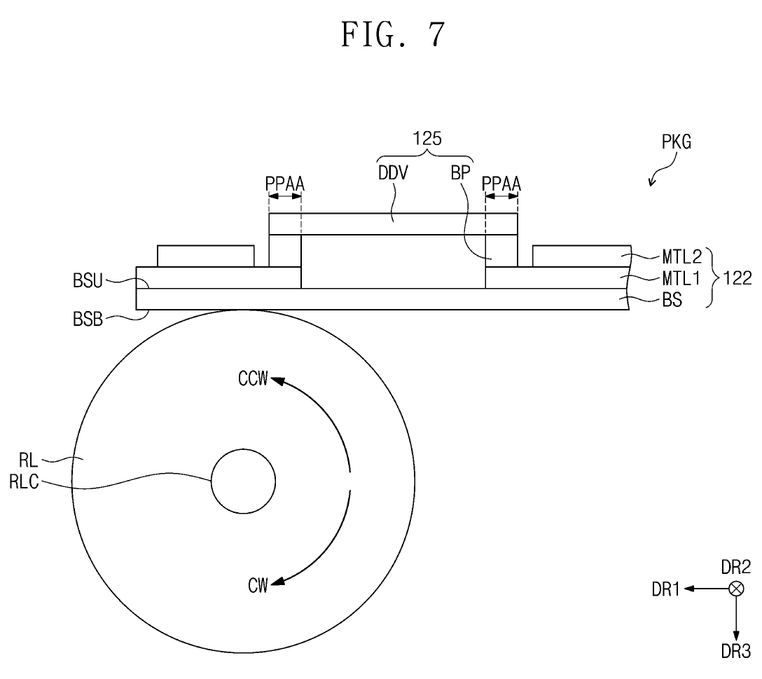

FIG. 3 is a plan view of an electronic apparatus according to an embodiment of the invention; and FIG. 4 is a cross-sectional view taken along line I-I' of FIG. 3. FIG. 5 and FIG. 6 are a cross-sectional view and a plan view, respectively, of some of the components shown in FIG. 3. Hereinafter, an electronic apparatus 10 according to an embodiment of the invention will be described with reference to FIGS. 3 to 6.

Referring to FIG. 3, an embodiment of the electronic apparatus 10 may operate based on an electrical signal. The electronic apparatus 10 may include various embodiments. In an embodiment, for example, the electronic apparatus 10 may include at least one selected from a display device that displays an image, and an input sensing device that senses an input such as a touch, pressure, light, or heat applied from an outside. Hereinafter, for convenience of description, embodiments in which the electronic apparatus 10 is implemented as a display device will be mainly described as an example.

In an embodiment, the electronic apparatus 10 may include a display panel 110, a circuit board 120, and a main circuit board 130. The display panel 110, the circuit board 120, and the main circuit board 130 may be electrically connected to each other.

In a plan view (or when viewed in a thickness direction), the display panel 110 may be divided into a display area DA, a peripheral area BA, and a pad area PA.

The display area DA may be an area on which an image is displayed. A plurality of pixels PX that implement the image may be arranged in the display area DA. The pixels PX may be arranged in a matrix shape along a first direction DR1 and a second direction DR2. The display panel 110 may control the pixels PX to display various images. A third direction DR3 perpendicular to the first direction DR1 and the second direction DR2 may be the thickness direction of the display panel 110.

Each of the pixels PX may include a display element and a driving element. The display element may include various embodiments. In an embodiment, for example, the display element may be at least one selected from a liquid crystal capacitor, an organic light emitting diode, an electrophoretic element, and an electrowetting element, for example. However, this is merely an example, and the display element may include various embodiments as long as it can implement an image based on an electrical signal, and is not limited to any one embodiment.

The driving element may control the driving of each of the display elements of the pixels PX. The driving element may include a thin film transistor.

The peripheral area BA may be adjacent to the display area DA. Signal lines connected to the pixels PX may be disposed on the peripheral area BA. In an embodiment, the peripheral area BA may have a frame shape surrounding the display area DA. However, this is merely an example, and the peripheral area BA may have various shapes as long as it is adjacent to the display area DA, and is not limited to any one embodiment.

The pad area PA may be adjacent to the peripheral area BA. The pad area PA may be an area coupled to the circuit board 120. Although not shown, a plurality of pads (not shown) for electrical connection to the circuit board 120 may be disposed on the pad area PA. The display panel 110 may be electrically connected to external electronic components such as the circuit board 120 and the main circuit board 130 through the pad area PA.

Referring to FIG. 4, an embodiment of the display panel 110 may include a base substrate 112, a display element layer 114, and an encapsulation layer 116 stacked along the third direction DR3 in cross-section.

The base substrate 112 may serve as a base layer on which the display element layer 114 is disposed. The base substrate 112 may be a single layer or may include a plurality of insulating layers. The base substrate 112 may be at least one selected from a glass substrate, a plastic substrate, a film, and a laminate including a plurality of organic films and/or inorganic films, and is not limited to any one embodiment.

Although not shown, the base substrate 112 may include the driving elements and signal lines of the pixels PX described above. Accordingly, the base substrate 112 may have a stacked structure including a plurality of conductive layers and a plurality of organic films and/or inorganic films.

The display element layer 114 may be disposed on the base substrate 112. The display element layer 114 may be electrically connected to the driving elements and signal lines of the base substrate 112. The display element layer 114 may include the display elements in the above-described pixels PX. In an embodiment, for example, where the display panel 110 is an organic light emitting display panel, the display element layer 114 may include an organic light emitting layer. The display area DA may correspond to an area on which the display element layer 114 is disposed.

The encapsulation layer 116 may be disposed on the display element layer 114 and cover the display element layer 114. The encapsulation layer 116 may protect the display element layer 114. Although not shown, the encapsulation layer 116 may cover a side surface of the display element layer 114. In addition, depending on the type of the display panel 110, the encapsulation layer 116 may be omitted or replaced with another display substrate.

Referring to FIGS. 3 and 4, in an embodiment, the circuit board 120 may be disposed on a part of the pad area PA of the display panel 110 to connect the main circuit board 130 and the display panel 110. The circuit board 120 may be disposed at one side (or surface) of the display panel 110 extending along a second direction DR2.

The circuit board 120 may be provided in plurality and arranged along the second direction DR2. However, this is merely an example, and the circuit board 120 may be provided as a single component and is not limited to any one embodiment.

In an embodiment, the circuit board 120 may include a line board 122 and a driving circuit 125. The line board 122 and the driving circuit 125 will be described in greater detail with reference to FIGS. 5 and 6.

Referring to FIGS. 5 and 6, in an embodiment, the line board 122 may include a base layer BS, bumps BP, and a plurality of pads IPD-120 and OPD-120.

The base layer BS may have a rectangular shape on a plane or in a plan view. In an embodiment, for example, the base layer BS may include a first side S1 and a second side S2 each extending along the second direction DR2 and facing each other in a first direction DR1. The base layer BS may include a third side S3 and a fourth side S4 each extending along the first direction DR1 and facing each other in the second direction DR2. However, this is merely an example, and the base layer BS may have various shapes and may include a plurality of sides accordingly.

The pads IPD-120 and OPD-120 may be disposed on the base layer BS. The base layer BS may include polyimide (PI).

The pads IPD-120 and OPD-120 may include connection pads CPD, input pads IPD-120, and output pads OPD-120.

In an embodiment, the bumps BP are covered by the driving circuit 125, and are illustrated in FIG. 6 with dash lines overlapping the driving circuit 125 for ease of illustration. Each bump BP may electrically connect the driving circuit 125 and the line board 122 to each other.

Referring to FIGS. 3 and 6, the input pads IPD-120 may be connected to the main circuit board 130. The input pads IPD-120 may be disposed on an input pad area IPP-120 defined at one side of the line board 122. The input pad area IPP-120 may be defined at the second side S2. The input pad area IPP-120 may overlap the main circuit board 130 on a plane.

The output pads OPD-120 may be connected to the display panel 110. The output pads OPD-120 may be disposed on an output pad area OPP-120 defined at the other side of the line board 122. The output pad area OPP-120 may be defined at the first side S1. The output pad area OPP-120 may overlap the display panel 110 on a plane or in a plan view.

The input pads IPD-120 and the output pads OPD-120 may extend diagonally with respect to each of the first direction DR1 and the second direction DR2. The input pads IPD-120 may be arranged symmetrically on both opposing sides based on a center.

In an embodiment, as shown in FIG. 6, one pad row may be disposed in each of the input pad area IPP-120 and the output pad area OPP-120. The pad row may include a plurality of pads arranged along the second direction DR2. However, this is merely an example, and in one embodiment of the invention, a plurality of pad rows may be disposed in each of the input pad area IPP-120 and the output pad area OPP-120, and it is not limited to any one embodiment. In the present disclosure, the input pad area IPP-120 and the output pad area OPP-120 may be collectively referred to as a pad area PPAA.

In an embodiment, the driving circuit 125 may include at least one driving chip. In an embodiment, the circuit board 120 has a chip-on-film structure, but is not limited thereto.

A driving circuit 125 may be electrically connected to the bump BP of the line board 122. The driving circuit 125 may provide electrical signals for driving the display panel 110 to the display panel 110. In addition, the driving circuit 125 may process electrical signals output from the display panel 110 and provide the processed signals to a main circuit board 130.

The driving circuit 125 may include various embodiments. In an embodiment, for example, the driving circuit 125 may include a data driving circuit. In such an embodiment, the driving circuit 125 may include data pads electrically connected to data lines and control signal pads electrically connected to control signal lines, which are connected to a pad part (not shown) of the display panel 110. The data lines may be connected to the pixels PX, and the control signal lines may be connected to the gate driving circuit.

However, this is merely an example, and in another embodiment where the display panel 110 is a touch panel for detecting an externally applied touch, the driving circuit 125 may provide driving signals for detecting the touch. The electronic apparatus 10 according to an embodiment of the invention may include various driving circuits 125 and is not limited to any one embodiment.

Referring back to FIGS. 3 and 4, the main circuit board 130 may be connected to the circuit board 120. The main circuit board 130 may provide image data, control signals, power voltages, or the like to the display panel 110 or the driving circuit 125. The main circuit board 130 is a line board distinguished from the circuit board 120 and may include an active element and a passive element. The main circuit board 130 may be flexible or rigid and is not limited to any one embodiment.

The electronic apparatus 10 may further include a connection member 140 disposed between the main circuit board 130 and the circuit board 120 to electrically connect the main circuit board 130 and the circuit board 120, and disposed between the display panel 110 and the circuit board 120 to electrically connect the display panel 110 and the circuit board 120.

The connection member 140 may have electrical conductivity and may be adhesive. The connection member 140 may include a thermosetting or photosetting material. In an embodiment, for example, the connection member 140 may include an anisotropic conductive film.

The electronic apparatus 10 according to an embodiment of the invention may include electronic components 110, 120, and 130 having pads for electrical connection and may include the connection member 140 for bonding the electronic components 110, 120, and 130. Thus, the electronic apparatus 10 may facilitate electrical connection between a plurality of electronic components provided separately and independently.

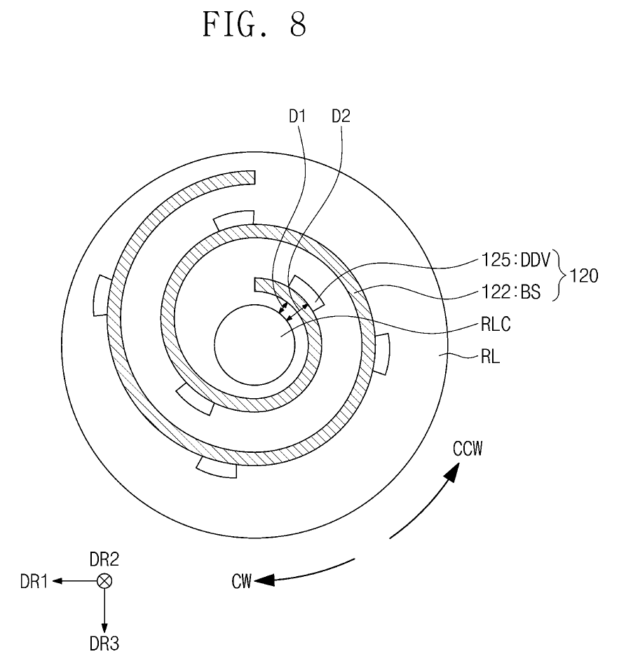

FIG. 7 is a cross-sectional view of an apparatus for packaging the circuit board according to an embodiment of the invention.

Referring to FIG. 7, an embodiment of the apparatus PKG for packaging the circuit board may include a reel RL and the circuit board 120.

The reel RL may rotate in a first rotation direction CCW and a second rotation direction CW opposite to the first rotation direction CCW. The reel RL may rotate with a center portion RLC thereof fixed. The circuit board 120 may be disposed in an internal space of the reel RL. The reel RL may be disposed on a bottom surface BSB of a base layer BS. When the reel RL is disposed on the bottom surface BSB of the base layer BS and rotated in the second rotation direction CW to allow the circuit board 120 to be disposed inside the reel RL, the base layer BS may be disposed between a driving chip DDV and the center portion RLC of the reel RL.

In an embodiment, the circuit board 120 may include the base layer BS, a first metal layer MTL1, a second metal layer MTL2, the bump BP, and the driving chip DDV.

The pad area PPAA may be defined on the base layer BS. The first metal layer MTL1 may be disposed on a top surface BSU of the base layer BS. The first metal layer MTL1 may include or be made of a metal composed of an alloy of copper and tin. However, in an embodiment where the first metal layer MTL1 transfers electrical signals to the driving chip DDV, the ratio of copper and tin in the first metal layer MTL1 may vary, and the first metal layer MTL1 may include or be made of another material.

The second metal layer MTL2 may be disposed on the first metal layer MTL1. The second metal layer MTL2 may be a solder resist layer. The second metal layer MTL2 may be disposed on the first metal layer MTL1 to protect the first metal layer MTL1.

When viewed on a plane or in a plan view, the bump BP may overlap the pad area PPAA and may be disposed on the top surface of the first metal layer MTL1. The bumps BP may electrically connect the driving chip DDV and the first metal layer MTL1 to each other. In the present disclosure, "when viewed on a plane" or “in a plan view” may mean viewed in a direction parallel to the third direction DR3 or a thickness direction of the base layer BS.

The driving chip DDV may be disposed on a top surface of the bump BP. The driving chip DDV may be a core semiconductor chip for driving the display panel 110 (see FIG. 3). The driving chip DDV may process signals of the display panel 110 and control the pixel PX (see FIG. 3). Inside the driving chip DDV, a digital-to-analog converter (DAC) for converting data signals and a timing controller (T-CON) function may be included. The first metal layer MTL1, the bump BP, and the driving chip DDV may be electrically connected to each other.

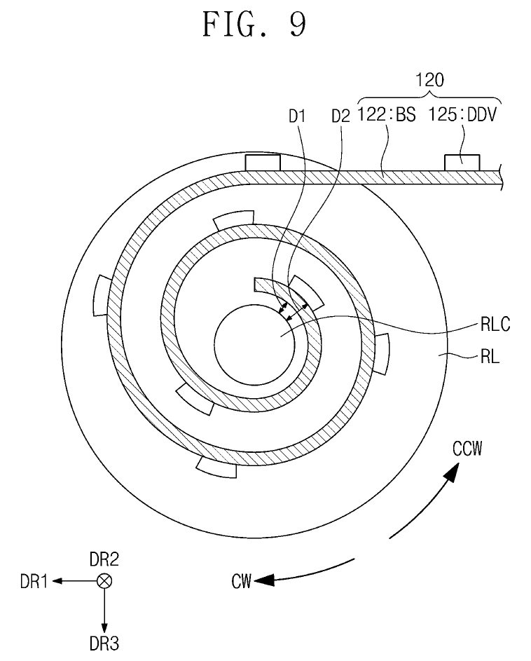

FIGS. 8 and 9 are cross-sectional views illustrating the inside of the reel according to embodiments of the invention.

Referring to FIGS. 7 and 8, in an embodiment, the circuit board 120 may be disposed inside the reel RL. The reel RL may be rotated in the first rotation direction CCW to place the circuit board 120 inside the reel RL. After the circuit board 120 is disposed inside the reel RL, the reel RL and the circuit board 120 may undergo thermal deformation. In a state where the circuit board 120 is disposed inside the reel RL, a distance D2 between the center portion RLC of the reel RL and the driving chip DDV may be greater than a distance D1 between the base layer BS and the center portion RLC where the driving chip DDV contacts. That is, the driving chip DDV may face in a direction opposite to the center portion RLC of the reel RL and may be wound inside the reel RL.

The driving chip DDV may be thermally cured while wound inside the reel RL so that the driving chip DDV is placed on the top surface BSU of the base layer BS. Thus, when the driving circuit 125 is disposed on the display panel 110 and the main circuit board 130 as illustrated in FIG. 4, it may be possible to effectively prevent the phenomenon that the line board 122 sags in a direction opposite to the third direction DR3 due to the weight of the driving circuit 125.

In an embodiment, a sagging amount of the line board 122 in the direction opposite to the third direction DR3 caused by the weight of the driving circuit 125 may be improved in FIG. 4. The driving circuit 125 may be wound around the reel RL with the line board 122 disposed between the driving circuit 125 and the reel RL inside the reel RL. In this state, heat may be applied to the reel RL. Subsequently, when the driving circuit 125 is disposed on the display panel 110, the thermally cured state of the line board 122 may eliminate or reduce the sagging amount of the line board 122 in the direction opposite to the third direction DR3.

Referring to FIGS. 7 and 9, the circuit board 120 may be disposed outside the reel RL by rotating the reel RL in the second rotation direction CW. The reel RL may be rotated in the second rotation direction CW, so that the circuit board 120 may be prepared to be mounted on the display panel 110 (see FIG. 3). When the circuit board 120 is exposed outside the reel RL, the circuit board 120 may be cut to a size suitable for mounting on the display panel 110 and mounted on the display panel 110.

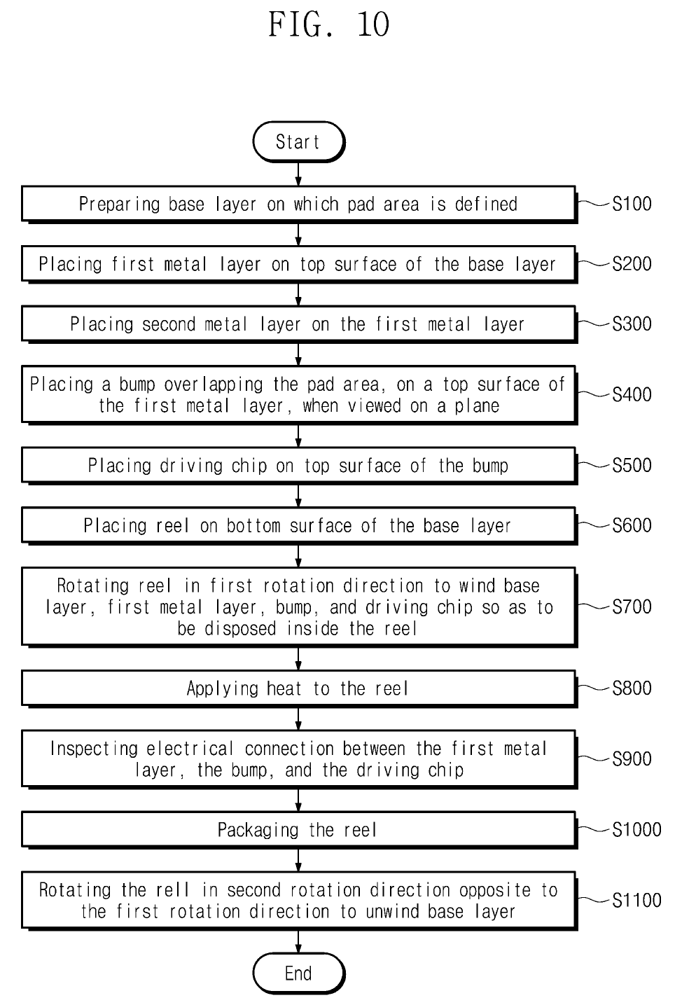

FIG. 10 is a flowchart of a method for manufacturing the circuit board according to an embodiment of the invention.

Referring to FIGS. 7 to 10, an embodiment of a method for manufacturing the circuit board may include a process (S100) of preparing a base layer BS on which a pad area PPAA is defined. An embodiment of the method for manufacturing the circuit board may further include a process (S200) of placing (or providing) a first metal layer MTL1 on a top surface of the base layer BS. The first metal layer MTL1 may include a compound of copper or tin.

An embodiment of the method for manufacturing the circuit board may further include a process (S300) of placing (or providing) a second metal layer MTL2 on the first metal layer MTL1. An embodiment of the method for manufacturing the circuit board may further include a process (S400) of placing (or providing) a bump BP on a top surface of the first metal layer MTL1 to overlap the pad area PPAA when viewed on a plane. The bump BP may be disposed on the top surface of the first metal layer MTL1 to connect electrical signals between a driving chip DDV and the first metal layer MTL1. An embodiment of the method of manufacturing the circuit board may further include a process (S500) of placing the driving chip DDV on a top surface of the bumps BP.

An embodiment of the method of manufacturing the circuit board may further include a process (S600) of placing (or disposing) a reel RL on a bottom surface (or inner surface) BSB of the base layer BS. The reel RL may be disposed on the bottom surface BSB of a base layer BS. The reel RL may be disposed on the bottom surface BSB of the base layer BS so that the base layer BS is disposed on the reel RL and the driving chip DDV is disposed on the base layer BS. That is, the base layer BS may be disposed between a center portion RLC of the reel RL and the driving chip DDV, and when a line board 122 is disposed inside the reel RL, the driving chip DDV may face outwardly toward an edge of the reel RL.

In a direction from the center portion RLC of the reel RL toward the edge of the reel RL, the base layer BS and the driving chip DDV may be stacked in this order. That is, the driving chip DDV is disposed on a top surface (or an outer surface) of the base layer BS. Due to the structure in which the base layer BS and the driving chip DDV are stacked in this order, during a process of mounting the circuit board 120 on the display panel 110 (see FIG. 4), sagging of the line board 122 in a direction toward the driving chip DDV (for example, in a direction opposite to a third direction DR3) may be reduced or eliminated.

An embodiment of the method for manufacturing the circuit board may further include a process (S700) of rotating the reel RL in a first rotation direction CCW so that the base layer BS, the first metal layer MTL1, the bumps BP, and the driving chip DDV are wound and disposed inside the reel RL. The circuit board 120 may be disposed inside the reel RL.

An embodiment of the method for manufacturing the circuit board may further include a process (S800) of applying heat to the reel RL. The process (S800) of applying heat to the reel RL may be performed at about 100°C or lower. Heat may be applied to the reel RL, so that the circuit board 120 may be thermally cured while being wound around the reel RL.

An embodiment of the method for manufacturing the circuit board may further include a process (S900) of inspecting electrical connections between the first metal layer MTL1, the bumps BP, and the driving chip DDV. The process (S900) of inspecting electrical connections may be performed after rotating the reel RL in a second rotation direction CW so that the circuit board 120 is disposed outside the reel RL.

An embodiment of the method for manufacturing the circuit board may further include a process (S1000) of packaging the reel RL. After inspecting the electrical connection of the circuit board 120, the reel RL may be rotated again in the first rotation direction CCW to place the circuit board 120 inside the reel RL, and then the reel RL may be packaged.

An embodiment of the method for manufacturing the circuit board may further include a process (S1100) of rotating the reel RL in the second rotation direction CW, which is opposite to the first rotation direction CCW, to unwind the base layer BS. During the manufacturing process of the circuit board 120, the circuit board 120 wound inside the reel RL may be rotated in the second rotation direction CW to be placed outside the reel RL, and the circuit board 120 may be manufactured in a structure that may be mounted on the display panel 110 (see FIG. 4).

As described above, in the method for manufacturing the circuit board according to an embodiment of the invention, the driving chip may be thermally deformed in a wound state inside the reel, and then thermally cured after being disposed on the top surface of the base layer.

Therefore, when the driving circuit is disposed on the display panel and the main circuit board, it may be possible to effectively prevent the circuit board from being deflected in the opposite direction of the third direction due to the weight of the driving circuit.

In such an embodiment, the driving circuit may be wound on the reel, and the line board may be disposed between the driving circuit and the reel.

Therefore, when the driving circuit is subsequently disposed on the display panel, the thermally cured state of the line board may eliminate or reduce a degree of deflection of the line board in the opposite direction of the third direction.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method for manufacturing a circuit board, the method comprising:
preparing a base layer on which a pad area is defined;
placing a first metal layer on a top surface of the base layer;
placing a bump overlapping the pad area, on a top surface of the first metal layer, when viewed in a thickness direction of the base layer;
placing a driving chip on a top surface of the bump;
placing a reel on a bottom surface of the base layer;
rotating the reel in a first rotation direction to wind the base layer, the first metal layer, the bump, and the driving chip to be disposed inside the reel; and
applying heat to the reel to package the reel.

2. The method of claim 1, further comprising placing a second metal layer on the first metal layer.

3. The method of claim 1, further comprising inspecting electrical connections between the first metal layer, the bump, and the driving chip.

4. The method of claim 1, wherein the applying the heat to the reel is performed at about 100°C or lower.

5. The method of claim 1, wherein the reel comprises a center portion, and
a distance between the driving chip and the center portion is greater than a distance between the base layer, which is in contact with the driving chip, and the center portion.

6. The method of claim 1, further comprising rotating the reel in a second rotation direction opposite to the first rotation direction to unwind the base layer.

7. An apparatus for packaging a circuit board, the apparatus comprising:
a reel which rotates in a first rotation direction and a second rotation direction opposite to the first rotation direction; and
a circuit board disposed inside the reel,
wherein the circuit board comprises:
a base layer on which a pad area is defined;
a first metal layer disposed on a top surface of the base layer;
a bump overlapping the pad area, disposed on a top surface of the first metal layer, when viewed in a thickness direction of the base layer; and
a driving chip disposed on a top surface of the bump,
wherein the reel is disposed on a bottom surface of the base layer.

8. The apparatus of claim 7, wherein the circuit board further comprises a second metal layer disposed on the first metal layer.

9. The apparatus of claim 7, wherein the first metal layer, the bump, and the driving chip are electrically connected to each other.

10. The apparatus of claim 7, wherein the reel and the circuit board are thermally deformed.

11. The apparatus of claim 7, wherein the reel comprises a center portion, and
a distance between the driving chip and the center portion is greater than a distance between the base layer, which is in contact with the driving chip, and the center portion.

12. The apparatus of claim 7, wherein the reel is rotated in the first rotation direction to place the circuit board inside the reel.

13. The apparatus of claim 7, wherein the reel is rotated in the second rotation direction to place the circuit board outside the reel.

14. An electronic apparatus comprising:
a display device which displays an image; and
a processor which processes an image signal and provides the processed image signal to the display device,
wherein the display device comprises a circuit board manufactured by:
preparing a base layer on which a pad area is defined;
placing a first metal layer on a top surface of the base layer;
placing a bump overlapping the pad area, on a top surface of the first metal layer, when viewed in a thickness direction of the base layer;
placing a driving chip on a top surface of the bump;
placing a reel on a bottom surface of the base layer;
rotating the reel in a first rotation direction to wind the base layer;
applying heat to the reel;
rotating the reel in a second rotation direction opposite to the first rotation direction to unwind the base layer; and
rotating the reel in the first rotation direction to place the base layer, the first metal layer, the bumps, and the driving chip inside the reel to perform the packaging.

15. The electronic apparatus of claim 14, wherein the circuit board further comprises a second metal layer disposed on the first metal layer.

16. The electronic apparatus of claim 14, wherein the first metal layer, the bump, and the driving chip are electrically connected to each other.

17. The electronic apparatus of claim 14, wherein the reel and the circuit board are thermally deformed.

18. The electronic apparatus of claim 14, wherein the reel comprises a center portion, and
a distance between the driving chip and the center portion is greater than a distance between the base layer in contact with the driving chip and the center portion.
